(19) United States
(12) Patent Application Publication
(10) Pub. No.: US 2021/0193459 A1
(43) Pub. Date: Jun. 24, 2021

(54) ORGANIC METAL COMPOUND, COMPOSITION FOR DEPOSITING THIN FILM COMPRISING THE ORGANIC METAL COMPOUND, MANUFACTURING METHOD FOR THIN FILM USING THE COMPOSITION, THIN FILM MANUFACTURED FROM THE COMPOSITION, AND SEMICONDUCTOR DEVICE INCLUDING THE THIN FILM

(71) Applicant: Samsung SDI Co., Ltd., Suwon-si (KR)

(72) Inventors: Sangkyun IM, Suwon-si (KR); Gyeong Ryeong BAK, Suwon-si (KR); Yong Tae KIM, Suwon-si (KR); Taegeun SEONG, Suwon-si (KR); Bukeun OH, Suwon-si (KR); Seol Hee LIM, Suwon-si (KR)

(21) Appl. No.: 17/108,961

(22) Filed: Dec. 1, 2020

(30) Foreign Application Priority Data
Dec. 23, 2019 (KR) 10-2019-0173308

(51) Int. Cl. H01L 21/02; C07F 17/00; C09K 11/06; C23C 16/455; C23C 16/40

(52) U.S. Cl. CPC H01L 21/02205; H01L 27/10805; C09K 11/06; H01L 21/02175; H01L 21/02181; H01L 21/02183; H01L 21/02186; H01L 21/02189; H01L 21/02271; H01L 21/0228; H01L 21/022; C23C 16/45525; C23C 16/404; C09K 2211/181; C09K 2211/1007; C07F 17/00

(57) ABSTRACT

An organometallic compound represented by Chemical Formula 1 may be used in a composition for depositing a thin film including the organometallic compound, where A is derived from a compound represented by Chemical Formula 2:

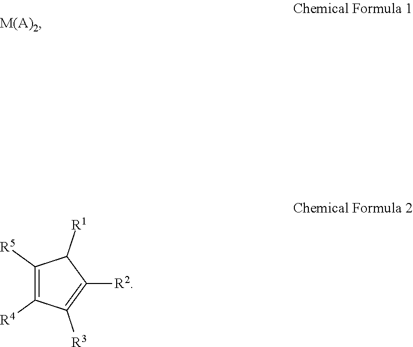

Embodiments of the present disclosure include the thin film, a manufacturing method for the thin film using the composition for depositing the thin film, and a semiconductor device including the thin film.

### CROSS-REFERENCE TO RELATED APPLICATION

This application claims priority to and the benefit of Korean Patent Application No. 10-2019-0173308 filed in the Korean Intellectual Property Office on Dec. 23, 2019, the entire content of which is incorporated herein by reference.

### BACKGROUND

### 1. Field

One or more aspects of embodiments of the present disclosure relate to an organometallic compound, a composition for depositing a thin film including the organometallic compound, a manufacturing method using the composition for depositing the thin film, a thin film manufactured from the composition for depositing the thin film, and a semiconductor device including the thin film.

### 2. Description of the Related Art

Recently, the semiconductor industry has progressed from a technology scale of hundreds of nanometers to ultra-fine technologies of several to tens of nanometers. In order to realize such ultra-fine technology, thin films having a high dielectric constant and low electrical resistance are essential.

However, due to high integration of semiconductor devices, it is difficult to form thin films by physical vapor deposition (PVD) or sputtering processes in the art. Accordingly, in recent years, thin films have been formed by chemical vapor deposition (CVD) processes or atomic layer deposition (ALD) processes.

In order to form substantially uniform thin films by a chemical vapor deposition process (CVD) or an atomic layer deposition process (ALD), thin film compositions that are easily vaporized and/or thermally stable are desired.

### SUMMARY

One or more aspects of embodiments of the present disclosure are directed toward an organometallic compound having low viscosity and/or improved volatility.

One or more aspects of embodiments of the present disclosure are directed toward a composition for depositing a thin film including the organometallic compound.

One or more aspects of embodiments of the present disclosure are directed toward a manufacturing method for the thin film using the composition for depositing the thin film.

One or more aspects of embodiments of the present disclosure are directed toward a thin film manufactured from the composition for depositing the thin film.

One or more aspects of embodiments of the present disclosure are directed toward a semiconductor device including the thin film.

One or more example embodiments of the present disclosure provide an organometallic compound represented by Chemical Formula 1:

M(A)₂. Chemical Formula 1

In Chemical Formula 1,

M may be Sr or Ba, and

A may be derived from a compound represented by Chemical Formula 2:

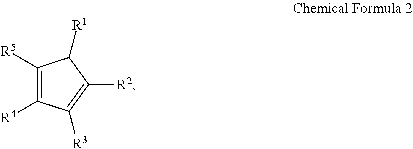

wherein in Chemical Formula 2,

R¹ to R⁵ may independently be hydrogen, or a substituted or unsubstituted C1 to C20 alkyl group, and

at least one of R¹ to R⁵ is a substituted or unsubstituted C3 to C20 branched alkyl group, and at least one of the remaining R¹ to R⁵ is a substituted or unsubstituted C1 to C20 alkyl group other than the substituted or unsubstituted C3 to C20 branched alkyl group (e.g., a substituted or unsubstituted C1 to C20 alkyl group different from the substituted or unsubstituted C3 to C20 branched alkyl group).

The at least one substituted or unsubstituted C3 to C20 branched alkyl group may be a substituted or unsubstituted C3 to C10 iso-alkyl group, a substituted or unsubstituted C3 to C10 sec-alkyl group, a substituted or unsubstituted C4 to C10 tert-alkyl group, or a substituted or unsubstituted C5 to C10 neo-alkyl group.

At least two of R¹ to R⁵ may be a substituted or unsubstituted C3 to C20 branched alkyl group.

In some embodiments, the at least two substituted or unsubstituted C3 to C20 branched alkyl groups may be the same.

One or two of R¹ to R⁵ may each independently be a substituted or unsubstituted C3 to C10 iso-alkyl group, and one or two of the remaining R¹ to R⁵ may each independently be a substituted or unsubstituted C1 to C20 linear alkyl group, a substituted or unsubstituted C3 to C10 sec-alkyl group, or a substituted or unsubstituted C4 to C10 tert-alkyl group.

One or two of R¹ to R⁵ may each independently be an iso-propyl group, an iso-butyl group, or an iso-pentyl group, and one or two of the remaining R¹ to R⁵ may each independently be a methyl group, an ethyl group, an n-propyl group, an n-butyl group, an n-pentyl group, an n-hexyl group, a sec-butyl group, a sec-pentyl group, a tert-butyl group, or a tert-pentyl group.

Chemical Formula 2 may be represented by one of Chemical Formulae 2-1 to 2-6:

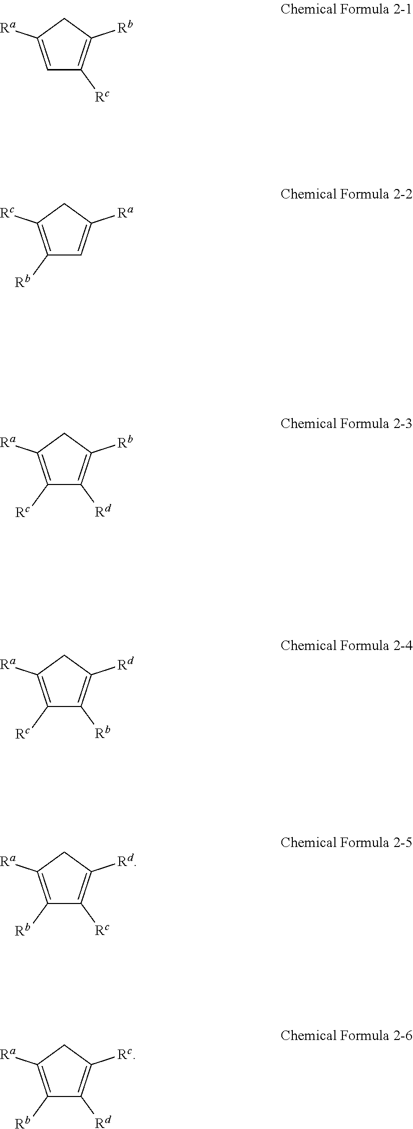

In Chemical Formulae 2-1 to 2-6,

R^{a} and R^{b} may each independently be an iso-propyl group, an iso-butyl group, or an iso-pentyl group, and

R^{c} and R^{d} may each independently be a methyl group, an ethyl group, an n-propyl group, an n-butyl group, an n-pentyl group, an n-hexyl group, a sec-butyl group, a sec-pentyl group, a tert-butyl group, or a tert-pentyl group.

The organometallic compound may be liquid at room temperature.

The organometallic compound may have a viscosity of less than or equal to about 1,000 cps measured according to (e.g., when measured under) the following conditions.

### [Viscosity Measurement Conditions]

Viscosity meter: RVDV-II (BROOKFIELD Company)

Spindle No.: CPA-40z

Torque/RPM: 20 to 80% Torque/1 to 100 RPM

Measurement temperature (sample cup temperature): 25° C.

According to thermogravimetric analysis under a 1 atm Ar (argon) gas atmosphere, a 50% weight loss relative to an initial weight of the organometallic compound may occur at about 50° C. to about 300° C.

One or more example embodiments of the present disclosure provide a composition for depositing a thin film including the organometallic compound.

The aforementioned composition for depositing the thin film may be a composition (e.g., first composition) for depositing a first thin film.

One or more example embodiments of the present disclosure provide a method of manufacturing a thin film including: vaporizing a composition for depositing a first thin film, and depositing the vaporized composition for depositing the first thin film on a substrate.

The method of manufacturing the thin film may further include vaporizing a composition (e.g., second composition) for depositing a second thin film, and

depositing the vaporized composition for depositing the second thin film on the substrate, wherein the composition for depositing the second thin film may include a second organometallic compound including titanium (Ti), zirconium (Zr), hafnium (Hf), niobium (Nb), tantalum (Ta), or a combination thereof.

The vaporized composition for depositing the first thin film and the vaporized composition for depositing the second thin film may be deposited together (e.g., simultaneously or concurrently, for example, in a mixture) or independently of each other on the substrate.

The vaporizing of the composition for depositing the first thin film may include heating the first composition for depositing the first thin film at a temperature of less than or equal to about 300° C.

The depositing of the vaporized composition for depositing the first thin film on a substrate may further include reacting the vaporized composition for depositing the first thin film with a reaction gas, and the reaction gas may include aqueous vapor (H₂O), oxygen (O₂), ozone (O₃), plasma, hydrogen peroxide (H₂O₂), ammonia (NH₃), hydrazine (N₂H₄), or a combination thereof.

The depositing of the vaporized composition for depositing the first thin film on a substrate may be performed using an atomic layer deposition (ALD) method or a metal organic chemical vapor deposition (MOCVD) method.

One or more example embodiments of the present disclosure provide a thin film manufactured from the composition (first composition) for depositing the thin film (first thin film).

One or more example embodiments of the present disclosure provide a semiconductor device including a thin film (e.g., the first thin film).

The organometallic compound according to an embodiment is in a liquid state at room temperature, and may exhibit low viscosity and/or desired (excellent) volatility. Accordingly, a semiconductor thin film may be easily manufactured using the organometallic compound according to an embodiment, and a semiconductor device may have high reliability for electrical characteristics by including the thin film.

### BRIEF DESCRIPTION OF THE DRAWINGS

FIGS. 1 to 6 are temperature-weight change rate graphs showing the rate of weight change according to applied temperature for the organometallic compounds according to Examples 1 to 4 and Comparative Examples 1 and 2, respectively.

### DETAILED DESCRIPTION

Hereinafter, embodiments of the present disclosure will be described in more detail so that those skilled in the art can easily implement the embodiments of the present disclosure. However, this disclosure may be embodied in many different forms and should not be construed as being limited to the example embodiments set forth herein.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, expressions such as “at least one of,” “one of,” and “selected from,” when preceding a list of elements, modify the entire list of elements and do not modify the individual elements of the list. As used herein, the term “and/or” includes any and all combinations of one or more of the associated listed items.

Further, the use of “may” when describing embodiments of the present disclosure refers to “one or more embodiments of the present disclosure”.

As used herein, when a definition is not otherwise provided, the term “a combination thereof” may refer to a mixture of constituents, a composite, a coordination compound, a laminate, an alloy, and/or the like.

As used herein, when a definition is not otherwise provided, the term “substituted” refers to replacement of a hydrogen atom by deuterium, a halogen, a hydroxy group, a cyano group, a nitro group, —NRR′ (wherein, R and R′ are independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C20 alkyl group, a C1 to C10 haloalkyl group, a C1 to C10 alkylsilyl group, a C3 to C30 cycloalkyl group, a C6 to C30 aryl group, a C1 to C20 alkoxy group, or a combination thereof. The term “unsubstituted” indicates that a hydrogen atom (e.g., all hydrogen atoms) is maintained without being replaced by another substituent.

As used herein, when a definition is not otherwise provided, the term “hetero” indicates that the functional group includes 1 to 3 heteroatoms selected from nitrogen (N), oxygen (O), sulfur (S) and phosphorus (P), and the remaining atoms may be carbon.

As used herein, when a definition is not otherwise provided, the term “alkyl group” refers to a linear or branched aliphatic hydrocarbon group. The alkyl group may be a “saturated alkyl group” without any double bonds or triple bonds. The alkyl group may be a C1 to C20 alkyl group. For example, the alkyl group may be a C1 to C10 alkyl group, a C1 to C8 alkyl group, a C1 to C6 alkyl group, or a C1 to C4 alkyl group. For example, the C1 to C4 alkyl group may be a methyl, ethyl, propyl, isopropyl, n-butyl, isobutyl, sec-butyl, or tert-butyl group.

As used herein, the term “saturated aliphatic hydrocarbon group” refers to a hydrocarbon group in which each carbon-carbon bond in a molecule is a single bond (unless otherwise defined). The saturated aliphatic hydrocarbon group may be a C1 to C20 saturated aliphatic hydrocarbon group. For example, the saturated aliphatic hydrocarbon group may be a C1 to C10 saturated aliphatic hydrocarbon group, a C1 to C8 saturated aliphatic hydrocarbon group, a C1 to C6 saturated aliphatic hydrocarbon group, a C1 to C4 saturated aliphatic hydrocarbon group, or a C1 to C2 saturated aliphatic hydrocarbon group. For example, the C1 to C6 saturated aliphatic hydrocarbon group may be a methyl group, an ethyl group, a propyl group, an isopropyl group, an n-butyl group, an isobutyl group, a sec-butyl group, a 2,2-dimethylpropyl group, or a tert-butyl group.

As used herein, the term “amine group” may refer to a primary amine group, a secondary amine group, or a tertiary amine group.

As used herein, the term “silyl amine group” may refer to a primary amine group, a secondary amine group, or a tertiary amine group in which the nitrogen atom is substituted with one or more silyl groups, and in some embodiments a hydrogen atom in the silyl group (substituent) may be replaced by a halogen atom (—F, —Cl, —Br, or —I), or a substituted or unsubstituted C1 to C20 alkyl group.

As used herein, the term “organometallic compound” may refer to a compound including a chemical bond between a metal element and a carbon, oxygen, or nitrogen atom, wherein the chemical bond may be or include a covalent bond, an ionic bond, and/or a coordination bond.

As used herein, the term “ligand” may refer to a molecule or ion that chemically bonds to a metal ion, and the molecule may be an organic molecule, wherein the chemical bond may be or include a covalent bond, an ionic bond, and/or a coordination bond.

As referred to herein, the viscosity may be measured under the following conditions:

### [Viscosity Measurement Conditions]

Viscosity meter: RVDV-II (BROOKFIELD Company)

Spindle No.: CPA-40z

Torque/RPM: 20-80% Torque/1-100 RPM

Measurement temperature (sample cup temperature): 25° C.

In order to manufacture a thin film having a high dielectric constant and/or high capacitance via a chemical vapor deposition (CVD) process or an atomic layer deposition (ALD) process, an organometallic compound including one or more organic ligands bonded to an alkaline earth metal or an alkaline earth metal is used. The alkaline-earth metal is a Group IIA element, and may include, for example, strontium (Sr), barium (Ba), or a combination thereof, and the organic ligand may be derived from a cyclopentadiene substituted with at least one substituted or unsubstituted C1 to C20 alkyl group. However, when the organometallic compound is mostly a solid or has a low vapor pressure, it may be difficult to form a substantially uniform thin film via a chemical vapor deposition (CVD) process or an atomic layer deposition (ALD) process. Accordingly, an organometallic compound that is thermally stable, easily vaporized, and has a high dielectric constant and/or high capacitance is desired.

An embodiment provides an organometallic compound represented by Chemical Formula 1:

M(A)₂. Chemical Formula 1

In Chemical Formula 1,

M may be an alkaline-earth metal, and

A may be derived from a compound represented by Chemical Formula 2:

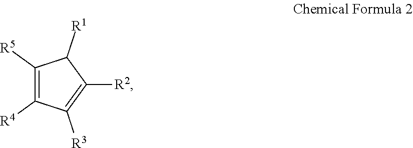

wherein, in Chemical Formula 2,

R¹ to R⁵ may each independently be hydrogen, or a substituted or unsubstituted C1 to C20 alkyl group, and

at least one of R¹ to R⁵ may be a substituted or unsubstituted C3 to C20 branched alkyl group, and at least one of the remaining R¹ to R⁵ may be a substituted or unsubstituted C1 to C20 alkyl group other than the substituted or unsubstituted C3 to C20 branched alkyl group.

The organometallic compound according to an embodiment includes an organic ligand represented by Chemical Formula 2 around the metal M, which may reduce the lattice energy of the organometallic compound, prevent or reduce stacking interactions between molecules of the organometallic compound, and thus decrease intermolecular attraction so that the organometallic compound is a liquid (e.g., at room temperature) having low viscosity and/or excellent volatility. Accordingly, the organometallic compound according to an embodiment may be desirably used as (e.g., in or for) a composition for depositing a thin film. In addition, the composition for depositing the thin film may exhibit a high dielectric constant, and may thus provide a thin film having a high capacitance.

Without being bound by the correctness of any particular explanation or theory, in the organometallic compound represented by Chemical Formula 1, the metal M may be single-bonded to one of the carbon atoms of at least one of the pentagonal rings of the two compounds represented by Chemical Formula 2, or may be bonded to at least one of the pentagonal rings of the two compounds represented by Chemical Formula 2 via the delocalized π electrons of each ring (e.g., in a haptic, half-sandwich, or sandwich mode).

For example, M may be a Group IIA element, for example, strontium, barium, or a combination thereof.

For example, in Chemical Formula 2, the substituted or unsubstituted C1 to C20 alkyl group may be a substituted or unsubstituted C1 to C20 linear alkyl group, a substituted or unsubstituted C3 to C20 branched alkyl group, or a combination thereof.

In some embodiments, in Chemical Formula 2, the substituted or unsubstituted C1 to C20 linear alkyl group may be a substituted or unsubstituted methyl group, a substituted or unsubstituted ethyl group, a substituted or unsubstituted n-propyl group, a substituted or unsubstituted n-butyl group, a substituted or unsubstituted n-pentyl group, a substituted or unsubstituted n-hexyl group, a substituted or unsubstituted n-heptyl group, a substituted or unsubstituted n-octyl group, or a combination thereof, but is not limited thereto.

In some embodiments, in Chemical Formula 2, the substituted or unsubstituted C3 to C20 branched alkyl group may be a substituted or unsubstituted C3 to C10 iso-alkyl group, a substituted or unsubstituted C3 to C10 sec-alkyl group, a substituted or unsubstituted C4 to C10 tert-alkyl group, a substituted or unsubstituted C5 to C10 neo-alkyl group, or a combination thereof. In some embodiments, the substituted or unsubstituted C3 to C20 branched alkyl group may be a substituted or unsubstituted iso-propyl group, a substituted or unsubstituted iso-butyl group, a substituted or unsubstituted sec-butyl group, a substituted or unsubstituted tert-butyl group, a substituted or unsubstituted iso-pentyl group, a substituted or unsubstituted sec-pentyl group, a substituted or unsubstituted tert-pentyl group, or a substituted or unsubstituted neo-pentyl group, and may desirably be a substituted or unsubstituted iso-propyl group, a substituted or unsubstituted iso-butyl group, a substituted or unsubstituted sec-butyl group, or a combination thereof, but is not limited thereto.

For example, the at least one substituted or unsubstituted C3 to C20 branched alkyl group (of R¹ to R⁵) may be a substituted or unsubstituted C3 to C10 iso-alkyl group, a substituted or unsubstituted C3 to C10 sec-alkyl group, a substituted or unsubstituted C4 to C10 tert-alkyl group, a substituted or unsubstituted C5 to C10 neo-alkyl group, or a combination thereof, and in some embodiments, the at least one substituted or unsubstituted C3 to C20 branched alkyl group (of R¹ to R⁵) may be a substituted or unsubstituted iso-propyl group, a substituted or unsubstituted iso-butyl group, a substituted or unsubstituted sec-butyl group, a substituted or unsubstituted tert-butyl group, a substituted or unsubstituted iso-pentyl group, a substituted or unsubstituted sec-pentyl group, a substituted or unsubstituted tert-pentyl group, or a substituted or unsubstituted neo-pentyl group, and in some embodiments may be a substituted or unsubstituted iso-propyl group, a substituted or unsubstituted sec-butyl group, or a combination thereof.

For example, at least two of R¹ to R⁵ may be a substituted or unsubstituted C3 to C20 branched alkyl group. The at least two substituted or unsubstituted C3 to C20 branched alkyl groups may be the same as or different from each other, and in some embodiments may be the same as each other. The substituted or unsubstituted C3 to C20 branched alkyl group may be the same as described above.

For example, at least one of the remaining R¹ to R⁵ may be a substituted or unsubstituted C3 to C20 branched alkyl group other than (e.g., different from) the at least one substituted or unsubstituted C3 to C20 branched alkyl group (of R¹ to R⁵), or may be a substituted or unsubstituted C1 to C20 linear alkyl group, or a combination thereof. The substituted or unsubstituted C3 to C20 branched alkyl group, and the substituted or unsubstituted C1 to C20 linear alkyl group may be the same as described above.

For example, one or two of the remaining R¹ to R⁵ may each independently be a substituted or unsubstituted C3 to C20 branched alkyl group other than (e.g., different from) the at least one substituted or unsubstituted C3 to C20 branched alkyl group, or may be a substituted or unsubstituted C1 to C20 linear alkyl group, or a combination thereof. The substituted or unsubstituted C3 to C20 branched alkyl group, and the substituted or unsubstituted C1 to C20 linear alkyl group may be the same as described above.

For example, at least one of R¹ to R⁵ may independently be a substituted or unsubstituted C3 to C10 iso-alkyl group, and at least one of the remaining R¹ to R⁵ may independently be a substituted or unsubstituted C1 to C20 linear alkyl group, a substituted or unsubstituted C3 to C10 sec-alkyl group, or a substituted or unsubstituted C4 to C10 tert-alkyl group.

For example, at least one of R¹ to R⁵ may independently be an iso-propyl group, an iso-butyl group, or an iso-pentyl group, and at least one of the remaining R¹ to R⁵ may independently be a methyl group, an ethyl group, an n-propyl group, an n-butyl group, an n-pentyl group, an n-hexyl group, a sec-butyl group, a sec-pentyl group, a tert-butyl group, or a tert-pentyl group.

For example, one or two of R¹ to R⁵ may each independently be the same as or different from each other, and may independently be a substituted or unsubstituted C3 to C10 iso-alkyl group, and one or two of the remaining R¹ to R⁵ may each independently be the same as or different from each other, and may independently be a substituted or unsubstituted C1 to C20 linear alkyl group, a substituted or unsubstituted C3 to C10 sec-alkyl group, or a substituted or unsubstituted C4 to C10 tert-alkyl group.

For example, one or two of R¹ to R⁵ may each independently be the same as or different from each other, and may independently be an iso-propyl group, an iso-butyl group, or an iso-pentyl group, and one or two of the remaining R¹ to R⁵ may each independently be the same as or different from each other, and may independently be a methyl group, an ethyl group, an n-propyl group, an n-butyl group, an n-pentyl group, an n-hexyl group, a sec-butyl group, a sec-pentyl group, a tert-butyl group, or a tert-pentyl group.

For example, in Chemical Formula 1, the two A's derived from Chemical Formula 2 may be the same as or different from each other, and in some embodiments may be the same as each other. For example, in the two A's derived from Chemical Formula 2, R¹ may be the same as or different from each other, and in some embodiments may be the same as each other, R² may be the same as or different from each other, and in some embodiments may be the same as each other, R³ may be the same as or different from each other, and in some embodiments may be the same as each other, R⁴ may be the same as or different from each other, and in some embodiments may be the same as each other, and R⁵ may be the same as or different from each other, and in some embodiments may be the same as each other.

The Chemical Formula 2 may be represented by one of Chemical Formulae 2-1 to 2-6:

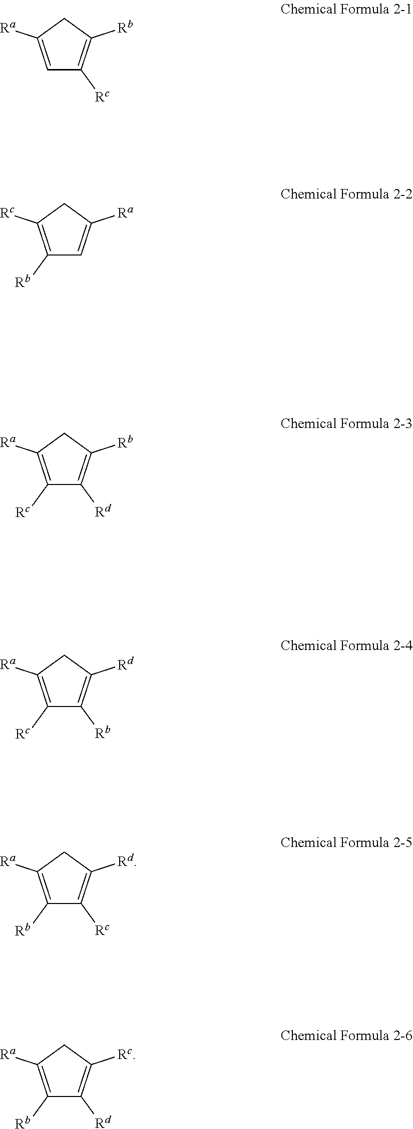

In Chemical Formulae 2-1 to 2-6,

R^{a} and R^{b} may independently be a substituted or unsubstituted C3 to C10 iso-alkyl group, and R^{c} and R^{d} may independently be a substituted or unsubstituted C1 to C20 linear alkyl group, a substituted or unsubstituted C3 to C10 sec-alkyl group, or a substituted or unsubstituted C4 to C10 tert-alkyl group.

For example, R^{a} and R^{b} may independently be an iso-propyl group, an iso-butyl group, or an iso-pentyl group, and R^{c} and R^{d} may independently be a methyl group, an ethyl group, an n-propyl group, an n-butyl group, an n-pentyl group, an n-hexyl group, a sec-butyl group, a sec-pentyl group, a tert-butyl group, or a tert-pentyl group.

For example, R^{a} and R^{b} may be the same as or different from each other and R^{c} and R^{d} may be the same as or different from each other, and in some embodiments R^{c} and R^{d} may be the same as each other.

For example, in Chemical Formula 1, the two A's derived from one of Chemical Formulae 2-1 to 2-6 may be the same or different from each other, and in some embodiments may be the same. For example, in Chemical Formulae 2-1 to 2-6, R^{a} may be the same as or different from each other, and in some embodiments may be the same, R^{b} may be the same as or different from each other, and in some embodiments may be the same, R^{c} may be the same as or different from each other, and in some embodiments may be the same, and R^{d} may be the same as or different from each other, and in some embodiments may be the same.

For example, the organometallic compound may be a liquid at room temperature (e.g., about 20±5° C., 1 atmosphere). Accordingly, transport of the organometallic compound through a fluid channel (Liquid Delivery System, LDS process) may be facilitated.

For example, the organometallic compound may have a viscosity of less than or equal to about 1,000 cps, for example, about 10 cps to about 1,000 cps, about 10 cps to about 500 cps, or about 10 cps to about 50 cps, measured according to (e.g., when measured under) the following conditions (e.g., viscosity measurement conditions). Accordingly, it may be easy to transport the organometallic compound through the fluid channel without a separate heating and warming process.

### [Viscosity Measurement Conditions]

Viscosity meter: RVDV-II (BROOKFIELD Company)

Spindle No.: CPA-40z

Torque/RPM: 20-80% Torque/1-100 RPM

Measurement temperature (sample cup temperature): 25° C.

For example, under thermogravimetric analysis under a 1 atm Ar (argon) gas atmosphere, a 50% weight loss relative to an initial weight of the organometallic compound may occur, for example, at about 50° C. to about 300° C., about 50° C. to about 250° C., or about 50° C. to about 200° C.

One or more example embodiments of the present disclosure provide a composition for depositing a thin film including the organometallic compound.

The composition for depositing the thin film may include one or two or more types of the aforementioned organometallic compound represented by Chemical Formula 1.

The composition for depositing the thin film may or may not further include a compound different from the organometallic compound represented by Chemical Formula 1, and in some embodiments may not further include a compound other than the aforementioned organometallic compound represented by Chemical Formula 1. For example, the composition may consist essentially of the organometallic compound represented by Chemical Formula 1.

When the composition for depositing the thin film further includes a compound different from the organometallic compound, the other compound different from the organometallic compound may be a compound including a non-shared (unshared) electron pair, and for example, the compound including the unshared electron pair may include at least one unshared electron pairs. In addition, the compound including the non-shared electron pair may include at least one heteroatom, and for example, the compound including the non-shared electron pair-containing compound may include one or two heteroatoms. The heteroatom may be N, 0, S, or a combination thereof. Accordingly, the stability of the organometallic compound may be improved, the viscosity of the composition for depositing the thin film may be further reduced, and/or volatility may be further improved.

For example, the compound including the non-shared electron pair may be an alkylamine-based, alkylphosphine-based, alkylamine oxide-based, alkylphosphine-oxide-based, ether-based, thioether-based compound, or a combination thereof. For example, the non-shared electron pair-containing compound may be a tertiary alkylamine, a tertiary alkylphosphine, a tertiary alkylamine oxide, a tertiary alkylphosphine oxide, a dialkylether, a dialkylthioether, or a combination thereof, but is not limited thereto.

For example, when the composition for depositing the thin film further includes the (another) compound different from the organometallic compound, the organometallic compound may be included in an amount of about 10 wt % to about 90 wt %, for example, about 15 wt % to about 80 wt %, about 20 wt % to about 70 wt %, or about 25 wt % to about 65 wt % based on a total weight of the composition for depositing the thin film.

For example, when the composition for depositing the thin film further includes the compound different from the organometallic compound, according to thermogravimetric analysis under a 1 atm Ar (argon) gas atmosphere, a 50% weight loss relative to an initial weight of the composition for depositing the thin film may occur at a lower temperature compared to that for the organometallic compound by itself, and compared to that for the compound including the non-shared electron pair by itself. For example, the volatility of the composition for depositing the thin film may be higher than the volatility of each of the organometallic compound and the compound including the non-shared electron pair, which are included in the composition for depositing the thin film. Accordingly, the composition for depositing the thin film may be easily vaporized and deposited at a relatively low temperature, and a uniform thin film may be formed.

In some embodiments, the aforementioned composition for depositing the thin film may further include other compounds in addition to the aforementioned organometallic compound and the compound including the non-shared electron pair.

The aforementioned composition for depositing the thin film may be a composition (e.g., first composition) for depositing a first thin film.

One or more example embodiments of the present disclosure provide a method of manufacturing a thin film that includes vaporizing a composition for depositing a first thin film and depositing the vaporized composition for depositing the first thin film on a substrate.

For example, the vaporizing of the composition for depositing the first thin film may include providing the composition for depositing the first thin film to a first reactor, and the providing of the composition for depositing the first thin film to the first reactor may include providing the composition for depositing the first thin film to the first reactor through a fluid channel.

For example, the vaporizing of the composition for depositing the first thin film may include heating the composition for depositing the first thin film to a temperature of less than or equal to about 300° C.

For example, the method of manufacturing the thin film may further include vaporizing a composition (e.g., second composition) for depositing a second thin film, and depositing the vaporized composition for depositing the second thin film on the substrate.

The composition for depositing the second thin film may include a second organometallic compound including titanium, zirconium, hafnium, niobium, tantalum, or a combination thereof, and the second organometallic compound may include an alkoxide-based ligand, an alkyl amide-based ligand, and a cyclopentadiene-based ligand, a β-diketonate-based ligand, a pyrrole-based ligand, an imidazole-based ligand, an amidinate-based ligand, or a combination thereof.

The composition for depositing the second thin film may or may not further include a solvent in addition to the second organometallic compound, and when the solvent is not further included, the second organometallic compound (e.g., the second composition) may be in a liquid state at room temperature (e.g., about 20±5° C., 1 atmosphere. When the composition for depositing the second thin film further includes a solvent, the solvent may be an organic solvent, for example, a polar solvent (such as diethyl ether, petroleum ether, tetrahydrofuran, and/or 1,2-dimethoxyethane). When the organic solvent is included, it may be included in a mole ratio of 2 times that of the organometallic compound. The organometallic compound included in the composition for depositing the second thin film may be coordinated by the organic solvent to improve the stability of the organometallic compound. For example, it may be possible to suppress the formation of oligomers caused by reactions between the central metal atoms of the organometallic compounds. In addition, the composition (for depositing the second thin film including the organic solvent) may further increase a vapor pressure of the monomeric organometallic compound.

For example, the vaporizing of the composition for depositing the second thin film may include providing the composition for depositing the second thin film to the first reactor or to a second reactor different from the first reactor (via a fluid channel).

For example, the vaporizing of the composition for depositing the second thin film may include heat-treating the composition for depositing the second thin film at a temperature of less than or equal to about 200° C., for example, heat-treating the composition for depositing the second thin film at a temperature of about 30° C. to about 200° C., about 30° C. to about 175° C., or about 30° C. to about 150° C.

For example, the composition for depositing the first thin film and the composition for depositing the second thin film may be vaporized together (e.g., simultaneously or as a mixture) or independently. When the composition for depositing the first thin film and the composition for depositing the second thin film are each independently vaporized, the vaporized composition for depositing the first thin film and the vaporized composition for depositing the second thin film may be deposited on a substrate together or independently, and they may be, for example, deposited alternately.

For example, the depositing of the vaporized composition for depositing the first thin film on the substrate may further include reacting the vaporized composition for depositing the first thin film with a reaction gas and the depositing of the vaporized composition for depositing the second thin film on the substrate may further include reacting the vaporized composition for depositing the second thin film with a reaction gas.

For example, the reaction gas may be an oxidizing agent, for example, aqueous vapor (H₂O), oxygen (O₂), ozone (O₃), plasma, hydrogen peroxide (H₂O₂), ammonia (NH₃), hydrazine (N₂H₄), or a combination thereof.

The deposition method is not particularly limited, but the method of manufacturing the thin film described above may be performed using an atomic layer deposition (ALD) or a metal organic chemical vapor deposition (MOCVD) method. For example, the depositing of the vaporized composition for depositing the first thin film, and/or the vaporized composition for depositing the second thin film on the substrate may be performed using an atomic layer deposition (ALD) or a metal organic chemical vapor deposition (MOCVD) method.

For example, the depositing of the vaporized composition for depositing the first thin film, and/or the vaporized composition for depositing the second thin film on the substrate may be performed at a temperature of about 100° C. to about 1000° C.

One or more example embodiments of the present disclosure provide a thin film manufactured from the composition for depositing the thin film. One or more example embodiments of the present disclosure provide a thin film manufactured using the composition for depositing the thin film.

For example, the thin film may be a perovskite thin film, and for example, the thin film may include a strontium titanium oxide, a barium strontium titanium oxide, a rubidium strontium oxide, or a combination thereof. In some embodiments, the thin film may include SrTiO₃, BaₓSr₁₋ₓTiO₃(wherein x is 0.1 to 0.9), SrRuO₃, SrCeO₃, or a combination thereof.

For example, a thickness of the thin film may be less than about 10 nm, and the dielectric constant value of the thin film may be greater than or equal to about 50, for example greater than or equal to about 110. Accordingly, the thin film may have a substantially uniform thickness and excellent leakage current characteristics while forming a fine pattern.

The thin film may be a uniform thin film exhibiting high dielectric constant and high capacitance, and/or excellent insulating properties. Accordingly, the thin film may be an insulating layer, and the insulating layer may be included in an electric or electronic device. The electric or electronic device may be a semiconductor device, and the semiconductor device may be, for example, a dynamic random-access memory (DRAM) device.

One or more example embodiments of the present disclosure provide a semiconductor device including a thin film as described above. Because the semiconductor device includes the thin film according to an embodiment, electrical characteristics and/or reliability may be improved.

Hereinafter, example embodiments are illustrated in more detail with reference to experimental examples. However, the scope of embodiments of the present disclosure is not limited thereto.

### Synthesis of Organometallic Compound

Hereinafter, an organometallic precursor compound for depositing an organometallic oxide and a metal-silicon oxide thin film, and a thin film deposition method according to the present disclosure will be described in more detail through the following examples and experimental examples. These are only presented to aid the understanding of the present disclosure, and the present disclosure is not limited to the following examples and experimental examples.

### EXAMPLE 1

### Synthesis of Organometallic Compound 1

Strontium metal (10.61 g, 0.121 mol), a compound represented by Chemical Formula 2a (55 g, 0.278 mol), and 300 mL of tetrahydrofuran (THF) were put in a flame-dried flask and cooled down to −78° C., and high purity ammonia gas (>5 N) was slowly injected thereto for 2 hours. The resultant was slowly warmed to room temperature for 5 hours, excess ammonia gas was removed, and the reaction was stirred for 24 hours under argon gas. The reaction was heated up to 50° C. under reduced pressure so that the THF was completely removed, and the residue was distilled under a reduced pressure to obtain Organometallic Compound 1. (yield: 51.9%, viscosity: 490 cps)

¹H NMR (Bruker, Ultraspin 300 MHZ, C₆D₆): δ 0.87 (s-Bu (CH₂-CH₃), m, 6H), δ 1.21 (i-Pr(CH—CH₃), m, 24H), δ 1.29 (s-Bu(CH—CH₃), m, 6H), δ 1.51 (s-Bu(CH—CH₂), m, 4H), δ 2.57 (s-BuCp(CH), m, 2H), δ 2.88 (i-PrCp(CH), m, 4H), δ 5.62 (Cp CH₂, m, 2H), δ 5.69 (Cp(CH), m, 1.5H) (wherein Cp is cyclopentadiene, i is iso, s is secondary, Pr is a propyl group, and Bu is a butyl group, respectively).

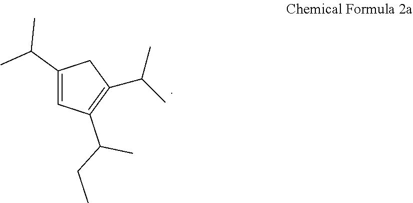

Organometallic Compound 1 may be represented by Chemical Formula 1a:

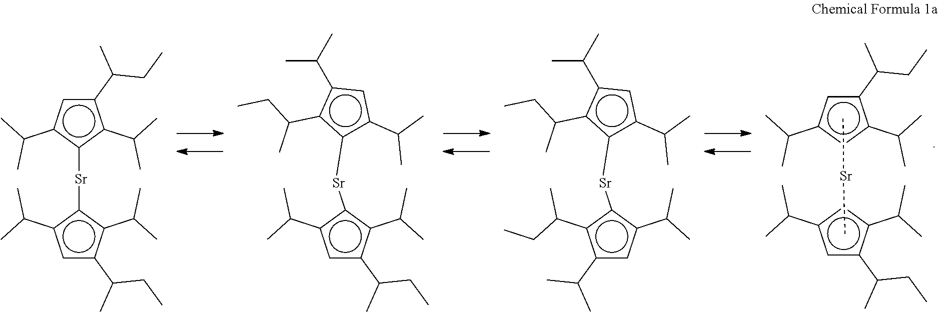

### EXAMPLE 2

### Synthesis of Organometallic Compound 2

Organometallic Compound 2 was obtained according to substantially the same method as Example 1, except that a smaller amount of strontium metal (2 g, 0.023 mol) was used, and a compound represented by Chemical Formula 2b (10.1 g, 0.053 mol) was used instead of the compound represented by Chemical Formula 2a (55 g, 0.278 mol). (yield: 55.2%, viscosity: 145,000 cps)

¹H NMR (Bruker, Ultraspin 300 MHZ, C₆D₆): δ 1.02 (n-Pr (CH₂-CH₃), m, 6H), δ 1.24 (i-Pr(CH—CH₃), m, 24H), δ 1.65 (n-Pr (CH₂-CH₂), m, 4H), δ 2.50 (n-PrCp CH₂, m, 4H), δ 2.91 (i-PrCp(CH), m, 4H), δ 6 5.53,5.64 (Cp CH_{2,} Cp(CH), m, 4H) (wherein Cp is cyclopentadiene, i is iso, n is normal, and Pr is a propyl group, respectively).

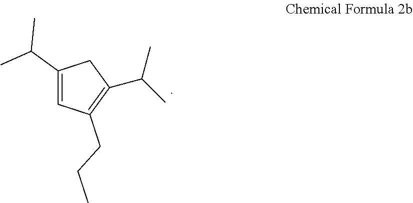

### EXAMPLE 3

### Synthesis of Organometallic Compound 3

Organometallic Compound 3 was obtained according to substantially the same method as Example 1, except that a smaller amount of strontium metal (2 g, 0.023 mol) was used, and a compound represented by Chemical Formula 2c (10.8 g, 0.053 mol) was used instead of the compound represented by Chemical Formula 2a (55 g, 0.278 mol). (yield: 54.8%, viscosity: 5,240 cps)

¹H NMR (Bruker, Ultraspin 300 MHZ, C₆D₆): δ 1.12 (Et (CH₂-CH₃), m, 12H), δ 1.23 (i-Pr(CH—CH₃), m, 24H), δ 2.44 (EtCp CH₂, m, 8H), δ 2.85 (i-PrCp(CH), m, 4H), δ 5.62 (Cp CH₂, m, 2.5H) (wherein Cp is cyclopentadiene, i is iso, Et is an ethyl group, and Pr is a propyl group, respectively)

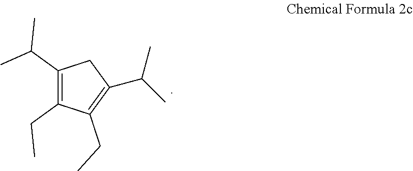

### EXAMPLE 4

### Synthesis of Organometallic Compound 4

Organometallic Compound 4 was obtained according to substantially the same method as Example 1, except that a smaller amount of strontium metal (2 g, 0.023 mol) was used, and a compound represented by Chemical Formula 2d (10.8 g, 0.053 mol) was used instead of the compound represented by Chemical Formula 2a (55 g, 0.278 mol). (yield: 50.6%, viscosity: 260 cps)

¹H NMR (Bruker, Ultraspin 300 MHZ, C₆D₆): δ 0.94 (s-Bu (CH₂-CH₃), m, 12H), δ 1.21 (i-Pr(CH—CH₃), m, 12H), δ 1.31 (s-Bu(CH—CH₃), m, 12H), δ 1.50 (s-Bu(CH—CH₂), m, 8H), δ 2.60 (s-BuCp(CH), m, 4H), δ 2.87 (i-PrCp(CH), m, 2H), δ 5.58 (Cp CH₂, m, 3H), δ 5.90 (Cp(CH), m, 0.5H) (wherein Cp is cyclopentadiene, i is iso, s is secondary, Pr is a propyl group, and Bu is a butyl group, respectively).

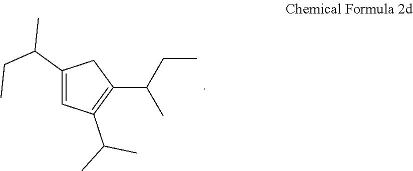 [SMILES: CCC(C)C1=CC(C(C)C)=C(C(C)CC)C1]

### COMPARATIVE EXAMPLE 1

### Synthesis of Comparative Organometallic Compound 1

Comparative Organometallic Compound 1 was obtained according to substantially the same method as Example 1, except that a smaller amount of strontium metal (2 g, 0.023 mol) was used, and a compound represented by Chemical Formula 2e (10.1 g, 0.053 mol) was used instead of the compound represented by Chemical Formula 2a (55 g, 0.278 mol). (yield: 57.1%, powder shape)

¹H NMR (Bruker, Ultraspin 300 MHZ, C₆D₆): δ 1.22, 1.30 (i-Pr(CH—CH₃), m, 36H), δ 2.88 (i-PrCp(CH), m, 6H), δ 5.63 (Cp CH₂, s, 3H), δ 5.81, 5.82 (Cp(CH), d, 0.5H) (wherein Cp is cyclopentadiene, i is iso, and Pr is a propyl group, respectively).

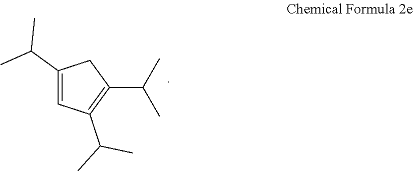

### COMPARATIVE EXAMPLE 2

### Synthesis of Comparative Organometallic Compound 2

Comparative Organometallic Compound 2 was obtained according to substantially the same method as Example 1, except that a smaller amount of strontium metal (2 g, 0.023 mol) was used, and a compound represented by Chemical Formula 2f (12.3 g, 0.053 mol) was used instead of the compound represented by Chemical Formula 2a (55 g, 0.278 mol). (yield: 49.6%, viscosity: 423 cps)

¹H NMR (Bruker, Ultraspin 300 MHZ, C₆D₆): δ 0.96 (s-Bu (CH₂-CH₃), m, 18H), δ 1.19,1.34 (s-Bu(CH—CH₃), m, 18H), δ 1.53 (s-Bu(CH—CH₂), m, 12H), δ 2.61 (s-BuCp(CH), m, 6H), δ 5.62 (Cp CH₂, m, 3H), δ 5.84 (Cp(CH), m, 0.5H) (wherein Cp is cyclopentadiene, s is secondary, and Bu is a butyl group, respectively).

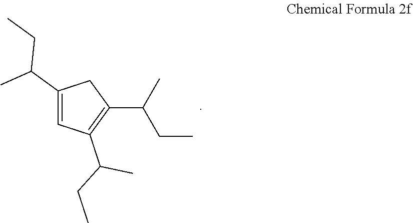 [SMILES: CCC(C)C1=CC(C(C)CC)=C(C(C)CC)C1]

### COMPARATIVE EXAMPLE 3

### Synthesis of Comparative Organometallic Compound 3

Comparative Organometallic Compound 3 was obtained according to substantially the same method as Example 1, except that a smaller amount of strontium metal (2 g, 0.023 mol) was used, and a compound represented by Chemical Formula 2g (10.1 g, 0.053 mol) was used instead of the compound represented by Chemical Formula 2a (55 g, 0.278 mol). (yield: 42.7%, powder shape)

¹H NMR (Bruker, Ultraspin 300 MHZ, C₆D₆): δ 0.94,0.97,0.99 (Et (CH₂-CH₃), t, 6H), δ 1.95,1.98 (MeCp(CH), d, 24H), δ 2.37,2.40,2.42,2.45 (EtCp CH₂, q, 4H) (wherein Cp is cyclopentadiene, Me is a methyl group, and Et is an ethyl group, respectively).

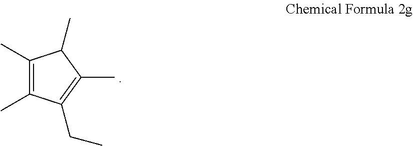

### Evaluation 1

The organometallic compounds according to Examples 1 to 4 and Comparative Examples 1 to 3 were each analyzed with respect to molecular weight, phase at room temperature (about 20±5° C., 1 atm), and viscosity, and the results are shown in Table 1.

The measuring conditions of the viscosity were as follows:

Viscosity meter: RVDV-II (BROOKFIELD Company)

Spindle No.: CPA-40z

Torque/RPM: 20-80% Torque/1-100 RPM

Measurement temperature (sample cup temperature): 25° C.

TABLE 1

| | Molecular | State at room | Viscosity |
|---|---|---|---|
| | weight | temperature | (cps) |
| Example 1 | 498.34 | liquid | 490 |
| Example 2 | 478.28 | liquid | 145,000 |
| Example 3 | 498.34 | liquid | 5,240 |
| Example 4 | 526.39 | liquid | 260 |
| Comparative | 470.28 | solid | — |
| Example 1 | | | |
| Comparative | 554.44 | liquid | 420 |
| Example 2 | | | |
| Comparative | 386.13 | solid | — |
| Example 3 | | | |

Referring to Table 1, the organometallic compounds according to Comparative Examples 1 and 3 were solid at room temperature, but the organometallic compounds according to Examples 1 to 4 were liquid at 25° C. and had a low viscosity of less than or equal to 1,000 cps.

### Evaluation 2

The organometallic compounds according to Examples 1 to 4 and Comparative Examples 1 and 2 were measured with respect to volatility under 1 atm depending on temperature using a thermogravimetric analysis (TGA) method.

The organometallic compounds according to Examples 1 to 4 and Comparative Examples 1 and 2 were individually aliquoted to 20±2 mg and put in an alumina sample container, and sample weight change rates with respect to temperature were measured, while heating up to 500° C. at 10° C./min.

The weight change rates were calculated according to Calculation Equation 1.

Weight change rate (%)=(weight after heat treatment/initial weight)×100% [Calculation Equation 1]

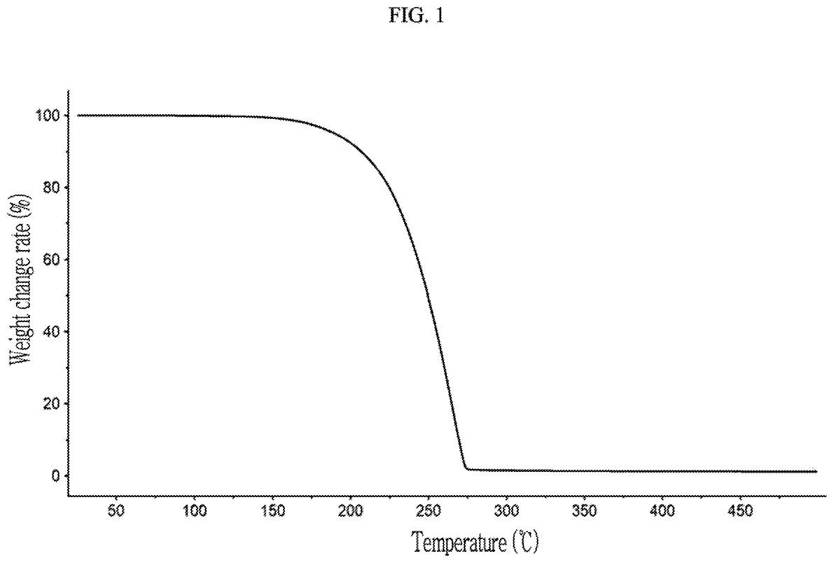

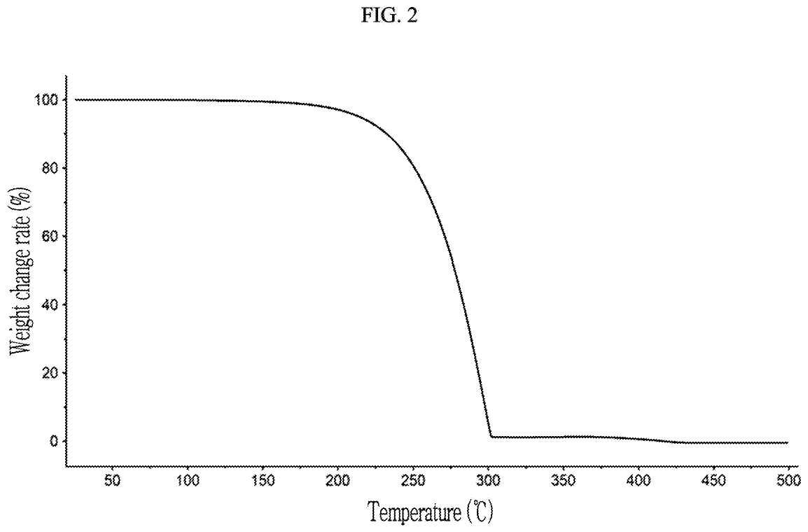

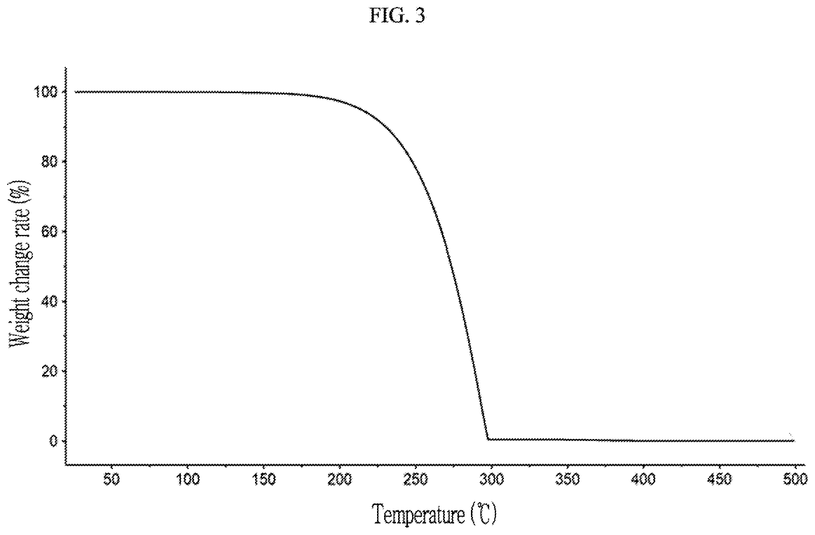

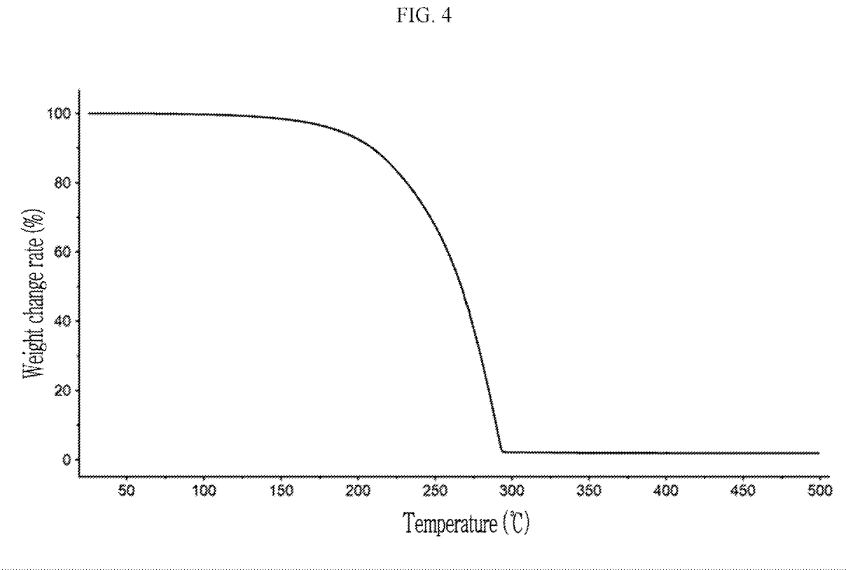

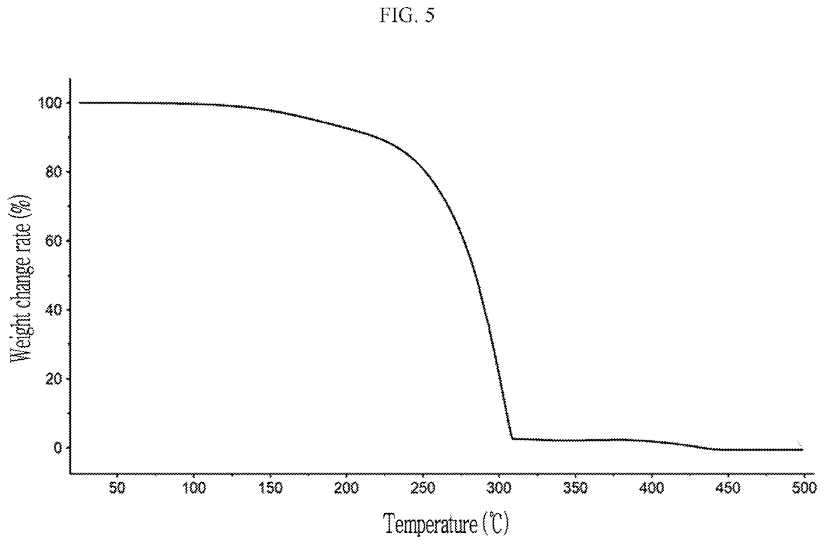

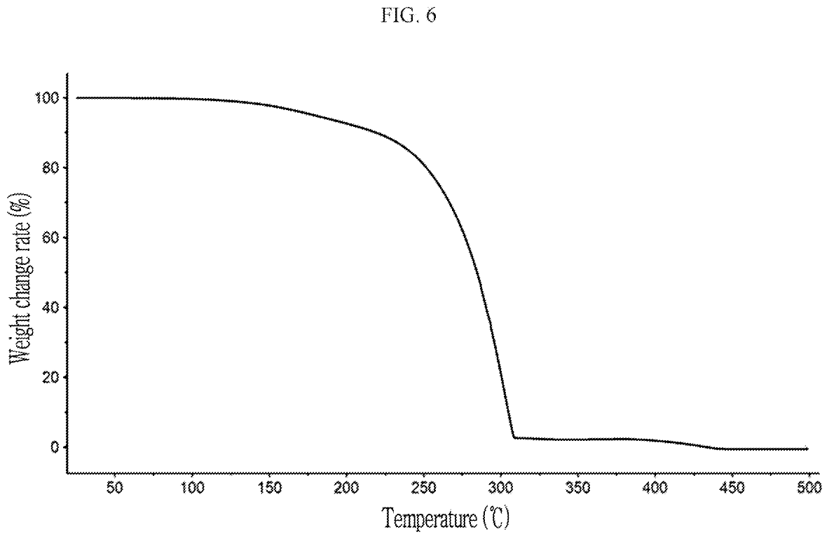

FIGS. 1 to 6 are temperature-weight change rate graphs showing the rate of weight change according to applied temperature for the organometallic compounds according to Examples 1 to 4 and Comparative Examples 1 and 2, respectively.

Referring to FIGS. 1 to 6, the organometallic compounds according to Examples 1 to 4 each exhibited a weight change rate of 50% at a lower temperature than those of each of Comparative Examples 1 and 2. Accordingly, the volatilities of the organometallic compounds according to Examples 1 to 4 were higher than those of the organometallic compounds according to Comparative Examples 1 and 2.

In summary, referring to Table 1 and FIGS. 1 to 6, the organometallic compounds of Examples 1 to 4 were liquid at room temperature and exhibited excellent volatility, and thus may be easily delivered through a fluid channel and easily gasified at a relatively low temperature and deposited.

### Manufacture of Thin Films

The organometallic compounds according to Examples 1 to 4 were respectively charged to 200 g in a 300 cc bubbler type canister and then, formed into thin films using ALD equipment.

In order to sufficiently supply the organometallic compounds, the canister was heated at 50° C. to 150° C., and in order to prevent or reduce condensation of the organometallic compounds in a pipe (e.g., during delivery), the pipe was heated to a temperature equal to that of the canister or greater than that of the canister by 10° C. Herein, Ar gas having high purity (99.999%) was used as carrier gas, and when the Ar gas was flowed at 50 to 500 sccm, the compositions for depositing the thin film were supplied. Then, ozone gas (as an oxidizing reagent gas) was flowed at 100 to 500 sccm, and while the temperature of the silicon substrate was changed into 200° C. to 450° C., the thin films were respectively deposited on a silicon substrate. The deposited thin films were heat-treated for several minutes at 650° C. using a RTA (rapid thermal anneal) equipment.

The growth per cycle (GPC) of the thin films depending on a deposit cycle was 1.05±0.05 Å/cycle, thickness uniformity (non-uniformity) of the thin films was 5.0±0.5%, and a crystalline phase was found in the thin films grown at greater than or equal to 340° C.

Hereinbefore, example embodiments of the present disclosure have been described and illustrated, however, it is apparent to a person with ordinary skill in the art that the present disclosure is not limited to the exemplary embodiment as described, and may be variously modified and transformed without departing from the spirit and scope of the present disclosure. Accordingly, the modified or transformed exemplary embodiments as such may not be understood separately from the technical ideas and aspects of the present disclosure, and the modified exemplary embodiments are within the scope of the following claims and equivalents thereof.

What is claimed is:

1. An organometallic compound represented by Chemical Formula 1:
M(A)₂,
wherein, in Chemical Formula 1,
M is Sr or Ba, and
A is derived from a compound represented by Chemical Formula 2, 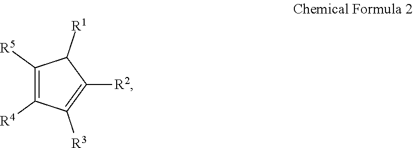
and wherein, in Chemical Formula 2,
R¹ to R⁵ are independently hydrogen, or a substituted or unsubstituted C1 to C20 alkyl group, and
at least one of R¹ to R⁵ is a substituted or unsubstituted C3 to C20 branched alkyl group, and at least one of the remaining R¹ to R⁵ is a substituted or unsubstituted C1 to C20 alkyl group other than the substituted or unsubstituted C3 to C20 branched alkyl group.

2. The organometallic compound of claim 1, wherein the at least one a substituted or unsubstituted C3 to C20 branched alkyl group is a substituted or unsubstituted C3 to C10 iso-alkyl group, a substituted or unsubstituted C3 to C10 sec-alkyl group, a substituted or unsubstituted C4 to C10 tert-alkyl group, or a substituted or unsubstituted C5 to C10 neo-alkyl group.

3. The organometallic compound of claim 1, wherein the at least two of R¹ to R⁵ are each independently a substituted or unsubstituted C3 to C20 branched alkyl group.

4. The organometallic compound of claim 3, wherein the at least two substituted or unsubstituted C3 to C20 branched alkyl groups are the same.

5. The organometallic compound of claim 1, wherein:
one or two of R¹ to R⁵ are each independently a substituted or unsubstituted C3 to C10 iso-alkyl group, and
one or two of the remaining R¹ to R⁵ are each independently a substituted or unsubstituted C1 to C20 linear alkyl group, a substituted or unsubstituted C3 to C10 sec-alkyl group, or a substituted or unsubstituted C4 to C1 0 tert-alkyl group.

6. The organometallic compound of claim 1, wherein:
one or two of R¹ to R⁵ are each independently an iso-propyl group, an iso-butyl group, or an iso-pentyl group, and
one or two of the remaining R¹ to R⁵ are each independently a methyl group, an ethyl group, an n-propyl group, an n-butyl group, an n-pentyl group, an n-hexyl group, a sec-butyl group, a sec-pentyl group, a tert-butyl group, or a tert-pentyl group.

7. The organometallic compound of claim 1, wherein Chemical Formula 2 is represented by one of Chemical Formulae 2-1 to 2-6: 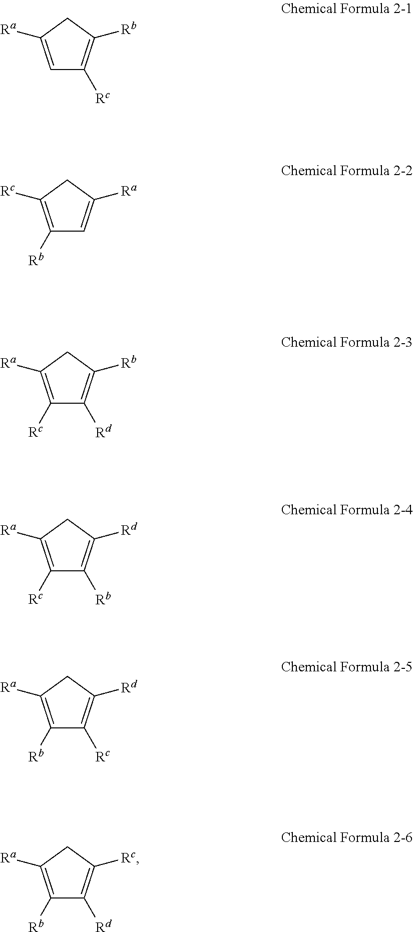
and wherein, in Chemical Formulae 2-1 to 2-6,
R^{a} and R^{b} are each independently an iso-propyl group, an iso-butyl group, or an iso-pentyl group, and
R^{c} and R^{d} are each independently a methyl group, an ethyl group, an n-propyl group, an n-butyl group, an n-pentyl group, an n-hexyl group, a sec-butyl group, a sec-pentyl group, a tert-butyl group, or a tert-pentyl group.

8. The organometallic compound of claim 1, wherein the organometallic compound is liquid at room temperature.

9. The organometallic compound of claim 1, wherein the organometallic compound has a viscosity of less than or equal to about 1,000 cps measured according to the following conditions:
Viscosity measurement conditions
Viscosity meter: RVDV-II (BROOKFIELD Company)
Spindle No.: CPA-40z
Torque/RPM: 20-80% Torque/1-100 RPM
Measurement temperature (sample cup temperature): 25° C.

10. The organometallic compound of claim 1, wherein according to thermogravimetric analysis under 1 atmosphere of Ar (argon) gas, a 50% weight loss relative to an initial weight of the organometallic compound occurs at about 50° C. to about 300° C.

11. A composition for depositing a thin film comprising the organometallic compound of claim 1.

12. A method of manufacturing a thin film comprising:
vaporizing the composition of claim 11 for depositing a first thin film, and
depositing the vaporized composition for depositing the first thin film on a substrate.

13. The method of claim 12, wherein the method of manufacturing the thin film further comprises:
vaporizing a composition for depositing a second thin film, and
depositing the vaporized composition for depositing the second thin film on the substrate,
wherein the composition for depositing the second thin film comprises a second organometallic compound comprising titanium, zirconium, hafnium, niobium, tantalum, or a combination thereof.

14. The method of claim 13, wherein the vaporized composition for depositing the first thin film and the vaporized composition for depositing the second thin film are deposited together or independently of each other on the substrate.

15. The method of claim 12, wherein the vaporizing of the composition for depositing the first thin film comprises heat-treating the composition for depositing the first thin film at a temperature of less than or equal to about 300° C.

16. The method of claim 12, wherein:
the depositing of the vaporized composition for depositing the first thin film on the substrate further comprises reacting the vaporized composition for depositing the first thin film with a reaction gas, and
the reaction gas comprises aqueous vapor (H₂O), oxygen (O₂), ozone (O₃), plasma, hydrogen peroxide (H₂O₂), ammonia (NH₃), hydrazine (N₂H₄), or a combination thereof.

17. The method of claim 12, wherein the depositing of the vaporized composition for depositing the first thin film on the substrate is performed utilizing an atomic layer deposition (ALD) process or a metal organic chemical vapor deposition (MOCVD) process.

18. A thin film manufactured from the composition of claim 11.

19. A semiconductor device comprising the thin film of claim 18.
